(19) United States
(12) Patent Application Publication
(10) Pub. No.: US 2010/0139084 A1
(43) Pub. Date: Jun. 10, 2010

(54) HEAD ASSEMBLY MANUFACTURING APPARATUS AND HEAD ASSEMBLY MANUFACTURING METHOD

(75) Inventor: Kazuyuki MIZUISHI, Ome-shi (JP)

Correspondence Address: KNOBBE MARTENS OLSON & BEAR LLP, 2040 MAIN STREET, FOURTEENTH FLOOR, IRVINE, CA, 92614, US

(73) Assignee: TOSHIBA STORAGE DEVICE CORPORATION, Tokyo (JP)

(21) Appl. No.: 12/704,219

(22) Filed: Feb. 11, 2010

Related U.S. Application Data
(63) Continuation of application No. PCT/JP2007/066003, filed on Aug. 17, 2007.

(51) Int. Cl. G11B 5/127; H05K 13/04

(52) U.S. Cl. 29/603.07; 29/729

(57) ABSTRACT

According to one embodiment, a head assembly manufacturing apparatus for manufacturing a head assembly including a load beam having a protrusion and a gimbal in contact with the load beam at the protrusion, includes: a heater configured to heat the protrusion from a back surface of the load beam; a thermal image forming module configured to form a first image which is a temperature distribution image of the gimbal by detecting infrared radiation emitted from a front surface of the gimbal; and a position detector configured to detect a position of the protrusion on the gimbal based on the first image formed by the thermal image forming module.

### CROSS-REFERENCE TO RELATED APPLICATIONS

This application is a continuation of PCT international application Ser. No. PCT/JP2007/066003 filed on Aug. 17, 2007 which designates the United States, incorporated herein by reference.

### BACKGROUND

1. Field

One embodiment of the invention relates to an apparatus and method for manufacturing a head assembly.

2. Description of the Related Art

Recently, a reduction in flying height and size of a magnetic head has been realized with an increase in capacity. Therefore, a high accuracy assembly of the magnetic head is required.

FIG. 4A is an exemplary front side perspective view of one conventional magnetic head assembly. FIG. 4B is an exemplary back side perspective view of the conventional magnetic head assembly. The magnetic head assembly 100 includes a suspension having a magnetic head slider 20 that records a signal on a magnetic recording medium or reproduces the signal, a gimbal 21 that provides a degree of freedom allowing the magnetic head slider 20 to swing, and a load beam 22 that presses the magnetic head slider 20 against the magnetic recording medium. The load beam 22 has a dimple 23 (protrusion) that applies a pivot load to the gimbal 21.

FIG. 5 is an exemplary side view of the conventional magnetic head assembly. The magnetic head slider 20 is disposed on a front surface side of the gimbal 21, and the load beam 22 is in contact with a back surface side of the gimbal 21 at the dimple 23. Thus, since the dimple 23 is located on the back surface side of the gimbal 21, the dimple 23 cannot be directly detected from the front surface side of the gimbal 21. Accordingly, when the magnetic head slider 20 is disposed on the front surface side of the gimbal 21, a positional deviation between the dimple 23 and the magnetic head slider 20 occurs as illustrated in FIG. 6. When the positional deviation occurs, a flying posture of the magnetic head slider 20 is deviated from the ideal state, and therefore, a variation in a flying height of the magnetic head slider 20 occurs.

In order to prevent the positional deviation, a conventional method for detecting positions of the magnetic head slider 20 and the suspension in the manufacture of the head assembly is described with reference to FIGS. 7A and 7B. As illustrated in FIG. 7B, a single CCD camera 200 is provided on the front surface side of the magnetic head assembly 100. As illustrated in FIG. 7A, reference holes 28, 29 indicating a position of the dimple 23 are provided in the load beam 22. Namely, since the CCD camera 200 cannot directly detect a center point of the dimple 23, the reference holes 28, 29 and a center point of the magnetic head slider 20 are detected, and then the magnetic head slider 20 is disposed so that distances from the center point of the magnetic head slider 20 to the respective reference holes 28, 29 are within predetermined distances respectively.

There has been known another position detecting method using CCD cameras provided respectively on front and back surface sides of a magnetic head assembly (see, Japanese Patent Application Publication (KOKAI) No. 2000-76611). In the position detecting method, as illustrated in FIG. 8, the CCD cameras 300, 400 are provided at two positions of the front and back surface sides of the magnetic head assembly 100. An image including a position of the dimple 23 and another image including the position of the magnetic head slider 20 are respectively taken by the CCD cameras 300, 400, and the taken images are compared with each other to detect a desired position.

However, in the method illustrated in FIGS. 7A and 7B, if a misalignment between the reference holes 28, 29 and the dimple 23 occurs due to variations in the manufacturing process of the suspension or the like, a misalignment between the magnetic head slider 20 and the dimple 23 also occurs.

Meanwhile, recently, with an increase in capacity of a magnetic disk device, the magnetic head is also required to be assembled with high accuracy. Accordingly, a manufacturing equipment for the magnetic head has become complicated, and it is difficult to place two CCD cameras like the method illustrated in FIG. 8. If a misalignment between the two CCD cameras occurs, the misalignment causes the positional deviation of the magnetic head slider 20.

### BRIEF DESCRIPTION OF THE SEVERAL VIEWS OF THE DRAWINGS

A general architecture that implements the various features of the invention will now be described with reference to the drawings. The drawings and the associated descriptions are provided to illustrate embodiments of the invention and not to limit the scope of the invention.

FIG. 1 is an exemplary block diagram of a magnetic head assembly manufacturing apparatus according to an embodiment of the invention;

FIG. 2 is an exemplary flow chart of a magnetic head assembly manufacturing processing in the embodiment;

FIG. 3 is an exemplary schematic view of a thermal image formed by an image forming module in the embodiment;

FIG. 4A is an exemplary front side perspective view of a magnetic head assembly;

FIG. 4B is an exemplary back side perspective view of the magnetic head assembly;

FIG. 5 is an exemplary side view of the magnetic head assembly;

FIG. 6 is an exemplary top view of the magnetic head assembly with a position deviation between a dimple and a magnetic head slider in the conventional magnetic head assembly;

FIG. 7A is an exemplary top view of a magnetic head assembly in one conventional position detecting method using a single CCD camera;

FIG. 7B is an exemplary side view of the CCD camera and the magnetic head assembly in the conventional position detecting method; and

FIG. 8 is an exemplary side view of two CCD cameras and a magnetic head assembly in another conventional position detecting method using the two CCD cameras provided on front and back surface sides of the magnetic head assembly.

### DETAILED DESCRIPTION

Various embodiments according to the invention will be described hereinafter with reference to the accompanying drawings. In general, according to one embodiment of the invention, a head assembly manufacturing apparatus is configured to manufacture a head assembly. The head assembly includes a load beam having a protrusion and a gimbal in contact with the load beam at the protrusion. The head assembly manufacturing apparatus includes: a heater configured to heat the protrusion from a back surface of the load beam; a thermal image forming module configured to form as a first image a temperature distribution image of the gimbal by detecting infrared radiation emitted from a front surface of the gimbal; and a position detector configured to detect a position of the protrusion on the gimbal based on the first image formed by the thermal image forming module.

According to another embodiment of the invention, a head assembly manufacturing method for manufacturing a head assembly including a load beam having a protrusion and a gimbal in contact with the load beam at the protrusion, includes: heating the protrusion from a back surface of the load beam; forming as a first image a temperature distribution image of the gimbal by detecting infrared radiation emitted from a front surface of the gimbal; and detecting a position of the protrusion on the gimbal based on the formed first image.

In one embodiments of the invention, a magnetic head assembly manufacturing apparatus is described as an example of a head assembly manufacturing apparatus. However, it is not limited to the magnetic head assembly manufacturing apparatus, but it is also applicable to a head assembly manufacturing apparatus configured to manufacture, for example, an optical head assembly in which an optical head used in an optical storage device is mounted on a head slider, and an optical magnetic head assembly in which an optical magnetic head is mounted on a head slider.

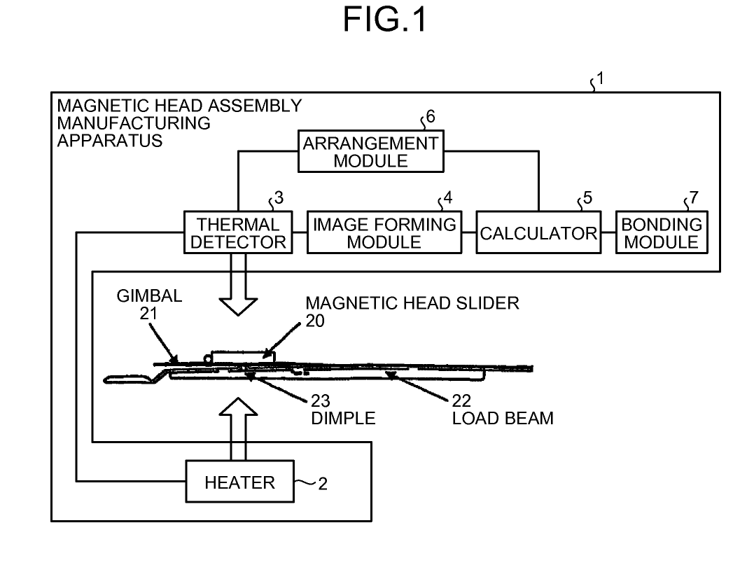

First, a hardware configuration of a magnetic head assembly manufacturing apparatus according to the embodiment of the invention will be described. FIG. 1 illustrates the hardware configuration of a magnetic head assembly manufacturing apparatus according to the embodiment. A magnetic head assembly manufacturing apparatus 1 according to the embodiment includes a heater 2, a thermal detector 3, an image forming module 4, a calculator 5, an arrangement module 6, and a bonding module 7.

The heater 2 applies a laser to a vicinity of a dimple 23 from a back surface of a load beam 22 to heat the dimple 23. The thermal detector 3 is disposed substantially perpendicular to a gimbal 21, and measures infrared radiation emitted from a front surface of the gimbal 21 to thereby detect a temperature distribution of the gimbal 21. The image forming module 4 forms a thermal image (a temperature distribution image) including the temperature distribution detected by the thermal detector 3.

The calculator 5 detects a position of the dimple 23 on the gimbal 21 and a center position of a magnetic head slider 20 based on the thermal image formed by the image forming module 4. The calculator 5 then determines whether a distance between the position of the dimple 23 and the center position of the magnetic head slider 20 is within a predetermined range. The arrangement module 6 arranges the magnetic head slider 20 on the front surface of the gimbal 21. When a determination result obtained from the calculator 5 is out of the predetermined range, the arrangement module 6 adjusts the arrangement position of the magnetic head slider 20.

The bonding module 7 applies an adhesive to the gimbal 21 to temporarily arrange the magnetic head slider 20 on the gimbal 21. When the determination result obtained from the calculator 5 is within the predetermined range, the bonding module 7 bonds the magnetic head slider 20 to a position arranged by the arrangement module 6 of the front surface of the gimbal 21.

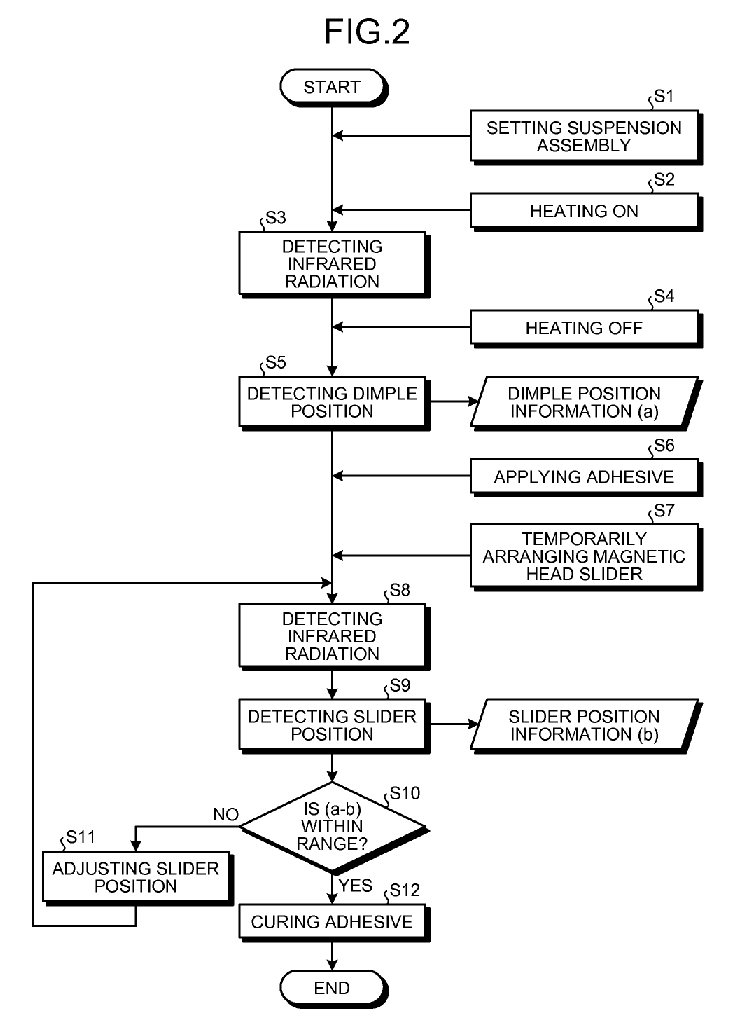

Next, processing in the magnetic head assembly manufacturing apparatus 1 is described with reference to a flow chart of FIG. 2. FIG. 2 illustrates a magnetic head assembly manufacturing processing in the embodiment.

The magnetic head assembly manufacturing apparatus 1 sets a suspension assembly at a predetermined position (S1). The suspension assembly includes the load beam 22 having the dimple 23 and the gimbal 21 in contact with the load beam 22 through the dimple 23. Next, in order to heat the dimple 23, the heater 2 applies the laser to the vicinity of the dimple 23 to thereby heat the dimple 23 to a predetermined temperature (S2). The heater 2 heats the dimple 23, whereby the heat is simultaneously transmitted to the gimbal 21 in contact with the dimple 23. In the present embodiment, the heater 2 heats the dimple 23 in a noncontact manner by laser application; however, the dimple 23 may be heated by any means.

Next, the thermal detector 3 measures infrared radiation emitted from the gimbal 21 to thereby detect the temperature distribution of the gimbal 21 (S3). Thereafter, the heater 2 stops the heating of the vicinity of the dimple 23 (S4).

In order to prevent false detection of the thermal detector 3, it is preferable that the heater 2 heats only the vicinity of the dimple 23 as possible, and adjusts the heating time (about 1 second in the present embodiment).

The image forming module 4 forms the thermal image (a first image) including the temperature distribution detected by the thermal detector 3.

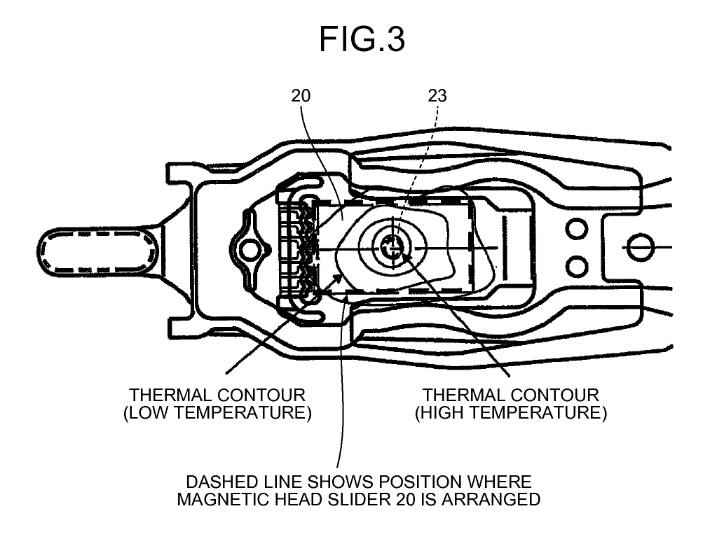

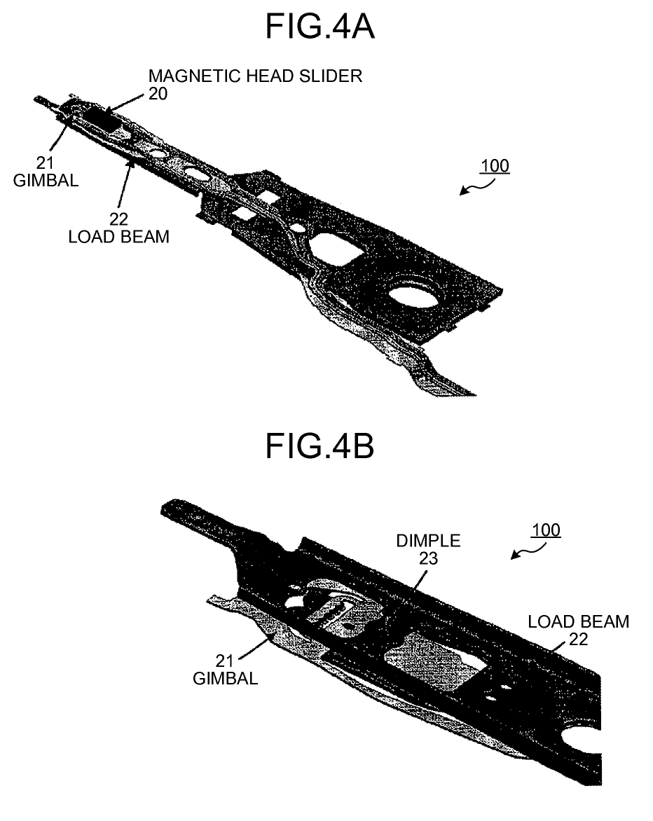

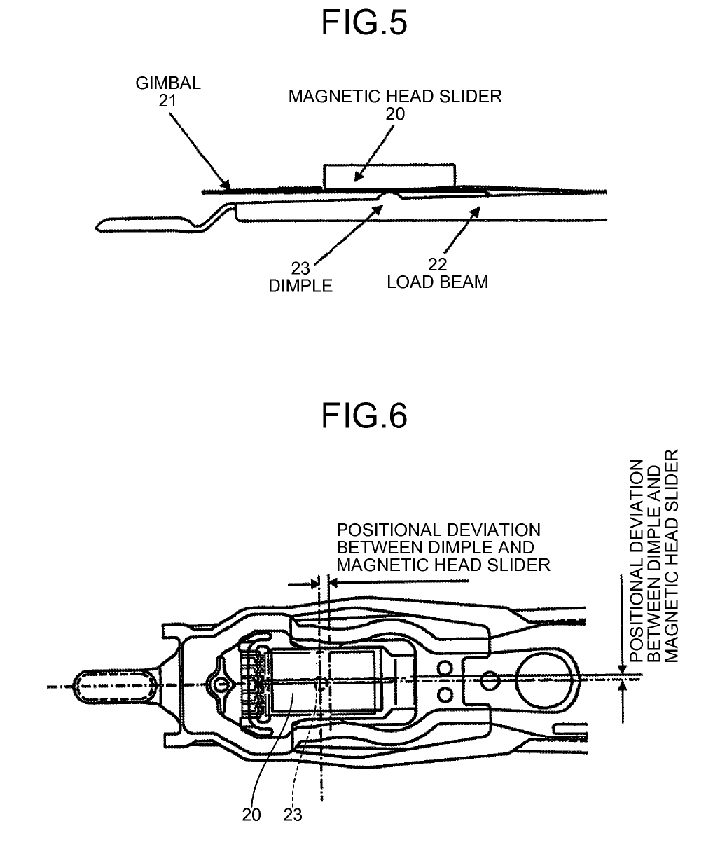

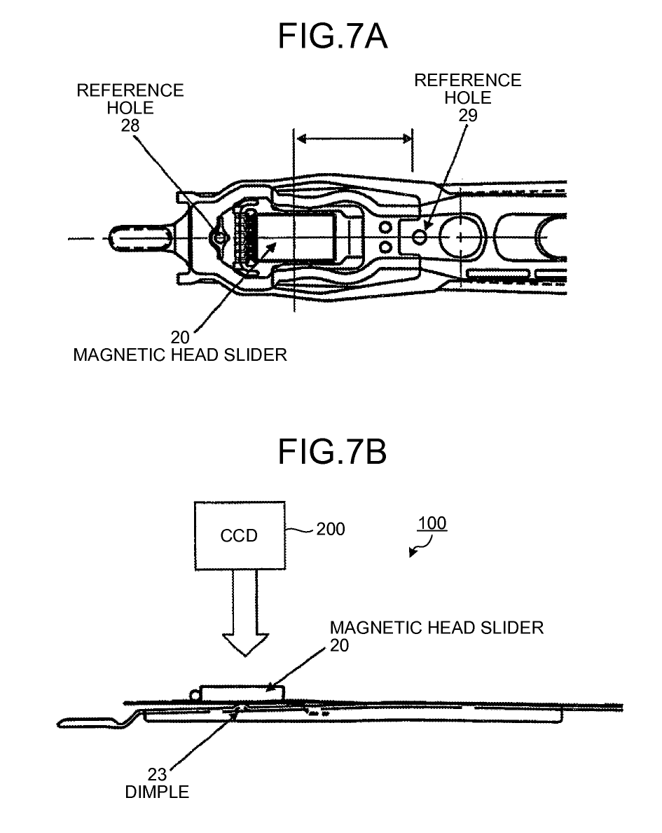

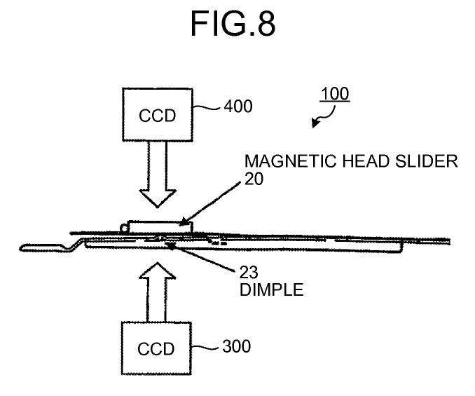

FIG. 3 is an exemplary schematic view of the thermal image formed by the image forming module 4. On the thermal image, the temperature distribution is illustrated as a thermal contour, and a difference in temperature is illustrated as a difference in color (for example, high temperature is illustrated by red color, and the lower the temperature, the more blue). The temperature of the gimbal 21 is high in the vicinity in contact with the dimple 23, and the more distant from the contact point with the dimple 23, the lower the temperature. Therefore, in the thermal image, for example, the vicinity in contact with the dimple 23 has a strong red component, and the more distant from the dimple 23, the stronger the blue components.

Based on the thermal image formed by the image forming module 4, the calculator 5 detects as dimple position information (pixel coordinates relative to the upper left corner of the thermal image) the position of the dimple 23 on the gimbal 21 (S5). The calculator 5 detects the position of the dimple 23 by determining, as the position of the dimple 23, the center of gravity (centroid point) of an area closed by the thermal contour corresponding to a predetermined temperature level in the thermal image. In order to reduce detection error, a temperature close to the highest temperature of temperature information that can be obtained from the thermal image is used as the predetermined temperature.

For example, the calculator 5 approximates the closed area by a polygon and calculates the center of gravity based on coordinates of each vertex of the polygon. In addition to the above method, for example, the calculator 5 respectively integrates X components (horizontal axis components of the thermal image) and Y components (vertical axis components of the thermal image) of pixels in the closed area and divides the integrated X components and the integrated Y components by the number of pixels in the area. The obtained value by the division is determined as the X component and the Y component of the center of gravity, whereby the position of the dimple 23 may be detected. Further, the calculator 5 determines, as the center of gravity, a center point of the thermal contour corresponding to the highest temperature level of the temperature information that can be obtained from the thermal image, whereby the position of the dimple 23 may be detected.

Next, in order to temporarily arrange the magnetic head slider 20 on the gimbal 21, the bonding module 7 applies the adhesive to the gimbal 21 (S6). The adhesive is a thermosetting adhesive. Next, the arrangement module 6 temporarily arranges the magnetic head slider 20 on the gimbal 21 so that the position of the dimple 23 approximately matches the center position of the magnetic head slider 20 (S7).

The thermal detector 3 detects the temperature distribution of the gimbal 21 by measuring infrared radiation emitted from the gimbal 21 on which the magnetic head slider 20 is temporarily arranged (S8). The image forming module 4 forms a thermal image (a second image) including the temperature distribution of the gimbal 21 on which the magnetic head slider 20 is temporarily arranged, detected by the thermal detector 3. Thereafter, based on the thermal image of the gimbal 21 on which the magnetic head slider 20 is temporarily arranged, the calculator 5 detects as slider position information (as in the dimple position information, pixel coordinates relative to the upper left corner of the thermal image) the center position of the magnetic head slider 20 on the gimbal 21 (S9).

The calculator 5 detects the center position of the magnetic head slider 20 by extracting a contour of the magnetic head slider 20 from the thermal image of the gimbal 21 on which the magnetic head slider 20 is temporarily arranged (the calculator 5 extracts the contour of the magnetic head slider 20 based on color difference between the magnetic head slider 20 and the gimbal 21. the temperature of the magnetic head slider 20 is lower than the temperature of the gimbal 21, so the color difference occurs).

Next, the calculator 5 calculates a difference between the dimple position information ((a) illustrated in FIG. 2) and the slider position information ((b) illustrated in FIG. 2) and determines whether the difference is within an allowable error range (the predetermined range) (S10). When the difference is within the allowable error range (Yes at S10), the bonding module 7 bonds the magnetic head slider 20 to the gimbal 21 by curing the applied adhesive (S12).

Meanwhile, when the difference between the dimple position information and the slider position information is out of the allowable error range (NO at S10), the arrangement module 6 adjusts the arrangement position of the magnetic head slider 20 (S11), the flow returns to step S8. The steps from S8 to S11 are repeated until the difference between the dimple position information and the slider position information falls within the allowable error range.

According to the embodiment, since the position of the dimple on the gimbal 21 can be easily detected, a variation in a flying height of the magnetic head slider due to a positional deviation between the magnetic head slider and the dimple can be reduced.

A thermal image forming module according to the invention corresponds to the thermal detector 3 and the image forming module 4 of the present embodiment. A position detector and a determiner according to the invention correspond to the calculator 5 of the present embodiment.

The various modules of the systems described herein can be implemented as software applications, hardware and/or software modules, or components on one or more computers, such as servers. While the various modules are illustrated separately, they may share some or all of the same underlying logic or code.

While certain embodiments of the inventions have been described, these embodiments have been presented by way of example only, and are not intended to limit the scope of the inventions. Indeed, the novel methods and systems described herein may be embodied in a variety of other forms; furthermore, various omissions, substitutions and changes in the form of the methods and systems described herein may be made without departing from the spirit of the inventions. The accompanying claims and their equivalents are intended to cover such forms or modifications as would fall within the scope and spirit of the inventions.

What is claimed is:

1. A head assembly manufacturing apparatus for manufacturing a head assembly comprising a load beam comprising a protrusion and a gimbal in contact with the load beam at the protrusion, comprising:
a heater configured to heat the protrusion from a back surface of the load beam;
a thermal image forming module configured to form a first image which is a temperature distribution image of the gimbal by detecting infrared radiation from a front surface of the gimbal; and
a position detector configured to detect a position of the protrusion on the gimbal based on the first image.

2. The head assembly manufacturing apparatus of claim 1, further comprising:
a positioning module configured to position a head slider on the front surface of the gimbal,
wherein the thermal image forming module is configured to further form a second image which is a temperature distribution image of the gimbal by detecting infrared radiation from the gimbal, and
the position detector is configured to further detect a center position of the top of the protrusion on the gimbal based on the second image.

3. The head assembly manufacturing apparatus of claim 2, further comprising a determiner configured to determine whether a distance between the position of the protrusion and the center position of the head slider detected by the position detector is within a predetermined range.

4. The head assembly manufacturing apparatus of claim 3, wherein the positioning module is configured to adjust a position of the head slider on the front surface of the gimbal, when the determiner determines that the distance is out of the predetermined range.

5. The head assembly manufacturing apparatus of claim 3, further comprising an attaching module configured to attach the head slider to the front surface of the gimbal when the determiner determines that the distance is within the predetermined range.

6. The head assembly manufacturing apparatus of claim 1, wherein the position detector is configured to detect a centroid point of a predetermined temperature region in the first image as the position of the protrusion on the gimbal.

7. The head assembly manufacturing apparatus of claim 2, wherein the position detector is configured to detect the center position of the top of protrusion based on a contour of the protrusion in the second image.

8. The head assembly manufacturing apparatus of claim 1, wherein the heater is configured to heat the protrusion by applying a laser to the protrusion.

9. The head assembly manufacturing apparatus of claim 5, wherein the attaching module is configured to attach the head slider to the gimbal with a thermosetting adhesive.

10. A head assembly manufacturing method for manufacturing a head assembly comprising a load beam comprising a protrusion and a gimbal in contact with the load beam at the protrusion, comprising:
heating the protrusion from a back surface of the load beam;
forming a first image which is a temperature distribution image of the gimbal by detecting infrared radiation from a front surface of the gimbal; and
detecting a position of the protrusion on the gimbal based on the first image.

11. The head assembly manufacturing method of claim 10, further comprising:
positioning a head slider on the front surface of the gimbal,
forming a second image which is a temperature distribution image of the gimbal by detecting infrared radiation from the gimbal; and
detecting a center position of the head slider on the gimbal based on the second image.

12. The head assembly manufacturing method of claim 11, further comprising determining whether a distance between the position of the protrusion and the center position of the head slider detected is within a predetermined range.

13. The head assembly manufacturing method of claim 12, further comprising adjusting a position of the head slider on the front surface of the gimbal when the determined distance is out of the predetermined range.

14. The head assembly manufacturing method of claim 12, further comprising attaching the head slider to the front surface of the gimbal when the determined distance is within the predetermined range.

15. The head assembly manufacturing method of claim 10, wherein a centroid point of a predetermined temperature region in the first image is detected as the position of the protrusion on the gimbal.

16. The head assembly manufacturing method of claim 11, wherein the center position of the head slider is detected based on a contour of the head slider in the second image.

17. The head assembly manufacturing method of claim 10, wherein the protrusion is heated by applying a laser to the protrusion.

18. The head assembly manufacturing method of claim 14, wherein the head slider is attached to the gimbal with a thermosetting adhesive.
